(19) United States
(12) Patent Application Publication
(10) Pub. No.: US 2023/0176472 A1
(43) Pub. Date: Jun. 8, 2023

(54) LITHOGRAPHIC METHOD BY USING A PHOTOMASK CONTAINED IN A TRANSPARENT POD

(71) Applicant: CHI-CHUNG CHEN, Tainan City (TW)

(72) Inventor: CHI-CHUNG CHEN, Tainan City (TW)

(21) Appl. No.: 17/858,075

(22) Filed: Jul. 6, 2022

(30) Foreign Application Priority Data
Dec. 8, 2021 (TW) 110145912

(51) Int. Cl. G03F 1/66; G03F 1/52; G03F 7/20

(52) U.S. Cl. CPC G03F 1/66; G03F 1/52; G03F 7/2002

(57) ABSTRACT

A lithographic method includes the step of providing a photomask with a pattern, the step of using a transparent pod to contain the photomask, the step of inserting the transparent pod in a lithographic machine, the step of using the lithograph machine to cast light onto the photomask via the transparent pod, and the step of transferring the pattern to a wafer.

### BACKGROUND OF INVENTION

### 1. Field of Invention

The present invention relates to a lithographic method by using a photomask and, more particularly, to a lithographic method by using a photomask contained in a transparent pod.

### 2. Related Prior Art

Photomasks are used in photolithography. During storage or transportation of a photomask, the photomask is very likely to suffer defects such as particles or smog caused by materials such as gas used in the photolithography, particles peeled from parts used in the photolithography, oil dropped from any of the parts, and/or other contaminants caused by deposition of and chemical reaction of gaseous molecules. Therefore, during the transportation or storage, the photomask is contained in a highly clean, air-tight and antistatic pod, Reticle SMIF Pod (“RSP”) to avoid contamination.

Conventionally, a robot is operated to take the photomask from the pod before the lithographic method. The surface of the photomask can be contaminated. Abrasion or collision can happen to the photomask to produce particles or static charges that render the face of the photomask more vulnerable to contamination. In such cases, the photomask must be cleaned and/or repaired. Such cleaning or repairing inevitably reduces the life of the photomask and jeopardize the yield of production of semiconductor products. Hence, there is a need for more spare photomasks, and this inevitably increases the cost of the production of the semiconductor products.

The present invention is therefore intended to obviate or at least alleviate the problems encountered in the prior art.

### SUMMARY OF INVENTION

It is an objective of the present invention to provide a lithographic method by using a photomask contained in a transparent pod.

It is another objective of the present invention to provide a lithographic method by using a photomask contained in a transparent pod without having to use a mechanism to take the photomask from the transparent pod.

To achieve the foregoing objectives, a lithographic method includes the step of providing a photomask with a pattern, the step of using a transparent pod to contain the photomask, the step of inserting the transparent pod in a lithographic machine, the step of using the lithograph machine to cast a light onto the photomask via the transparent pod, and the step of transferring the pattern to a wafer.

Other objectives, advantages and features of the present invention will be apparent from the following description referring to the attached drawings.

### BRIEF DESCRIPTION OF DRAWINGS

The present invention will be described via detailed illustration of two embodiments referring to the drawings wherein:

FIG. 1 is a flow chart of a lithographic method by using a photomask contained in a transparent pod according to the first embodiment of the present invention;

FIG. 2 is a cross-sectional view of a lithographic machine and a transparent pod used in the lithographic method shown in FIG. 1;

FIG. 3 is a perspective view of the transparent pod shown in FIG. 2;

FIG. 4 is an exploded view of the transparent pod shown in FIG. 3;

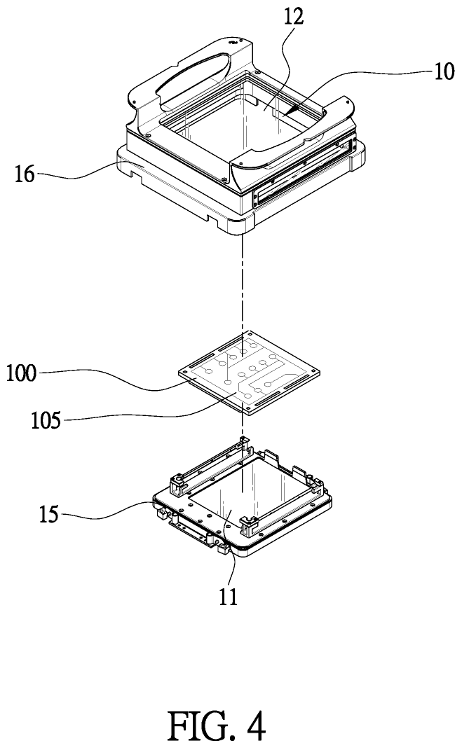

FIG. 5 is a top view of the transparent pod shown in FIG. 3; and

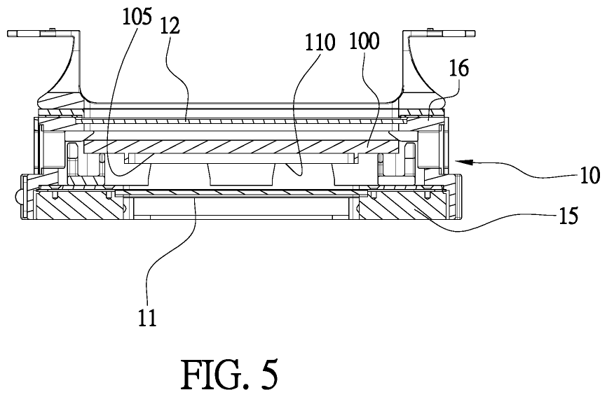

FIG. 6 is a flow chart of a lithographic method by using a photomask contained in a transparent pod according to the second embodiment of the present invention.

### DETAILED DESCRIPTION OF EMBODIMENTS

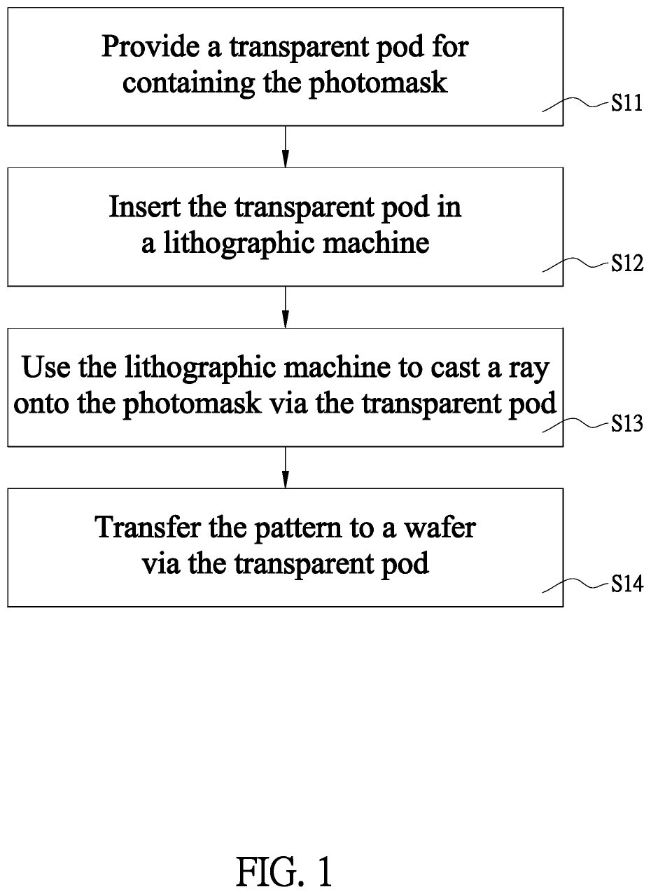

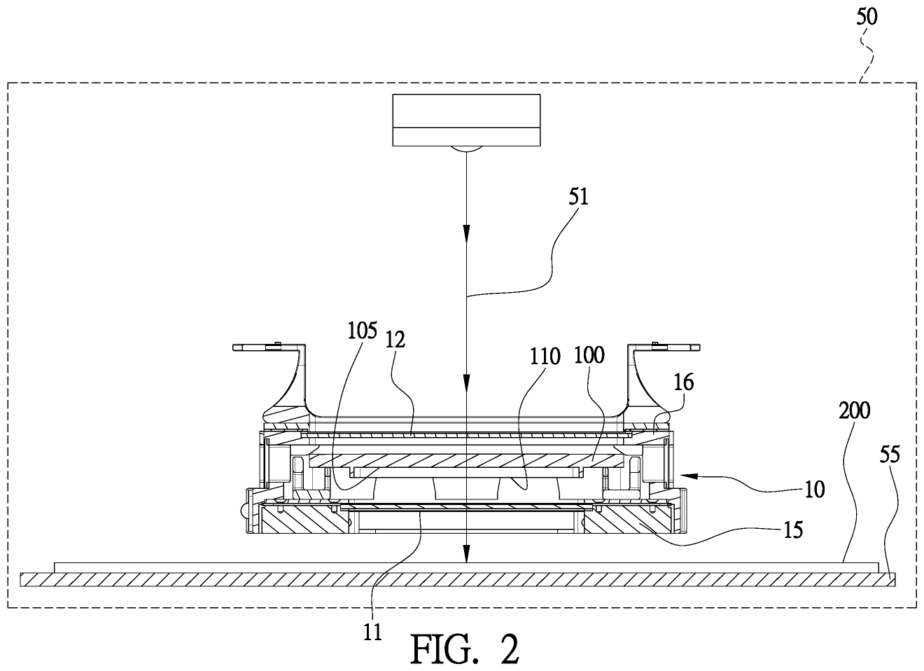

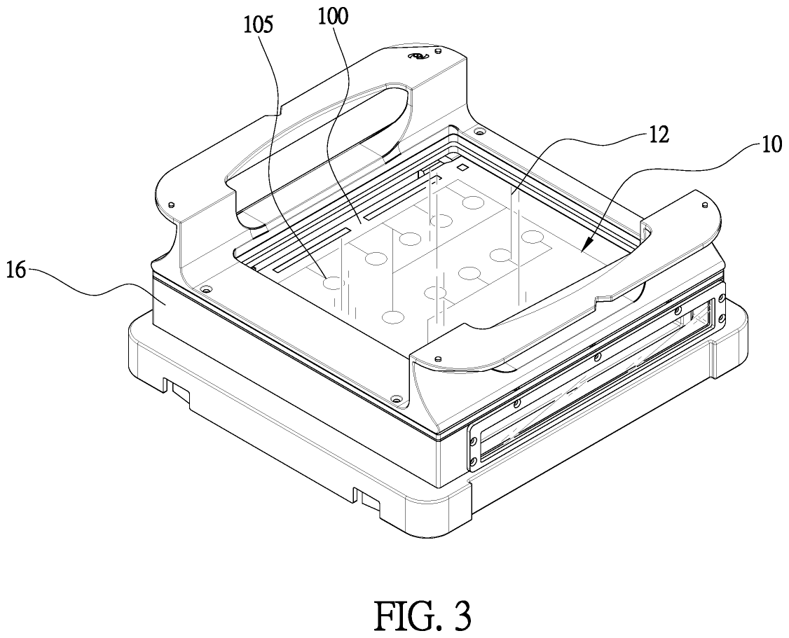

Referring to FIGS. 1 and 2, there is shown a lithographic method by using a photomask 100 according to first embodiment of the present invention. The photomask 100 includes lower and upper. The lower and upper faces are in parallel to each other. The lower or upper face of the photomask 100 is formed with a pattern 105 (FIG. 3) corresponding to a layout of a circuit. For example, the lower face of the photomask 100 is formed with the pattern 105. A transparent film 110 is preferably used to cover and protect the pattern 105.

The lithographic method includes providing a transparent pod for containing the photomask 100 at S11, inserting the transparent pod in a lithographic machine 50 at S12, using the lithographic machine 50 to cast a ray 51 onto the photomask 100 via the transparent pod at S13, and transferring the pattern 105 to a wafer 200 at S14.

At S11, the transparent pod is provided for containing the photomask 100. The transparent pod includes a lower lens 11 corresponding to the lower face and an upper lens 12 corresponding to the upper face. The lower and upper lenses 11 and 12 are made of a transmittance equal to or larger than 90%. Each of the lower and upper lenses 11 and 12 includes a transparent portion equal to or larger than the pattern 105 of the photomask 100.

Preferably, the lower and upper lenses 11 and 12 are made of 99.995% pure quartz so that they exhibit excellent transmittance regard ultraviolet light, visible light and infrared light.

The transparent pod includes a base 15 and a cover 16. The lower lens 11 is connected to the base 15. The upper lens 12 is connected to the cover 16. The base 15 and the cover 16 can be made of metal or plastic except for the lower and upper lenses 11 and 12.

At S12, the transparent pod is inserted in the lithographic machine 50. The transparent pod is inserted in the lithographic machine 50 after the photomask 100 is inserted in the transparent pod.

The lithographic machine 50 includes a light source (not numbered) located above a table 55. The light source is operable to emit a ray with a wavelength toward the table 55. For example, the lithographic machine 50 is operable to emit an ultraviolet ray, a deep ultraviolet ray, or an extreme ultraviolet ray.

At S13, the lithographic machine 50 is used to cast the ray 51 onto the upper face of the photomask 100 through the upper lens 12.

Then, the ray 51 penetrates the photomask 100. A first portion of the ray 51 is blocked by the pattern 105 while a second portion of the ray 51 goes through the lower face of the photo mask 100. Via the lower lens 11, the second portion of the ray 51 goes to the wafer 200 that is supported on the table 55, below the transparent pod.

At S14, the pattern 105 is transferred to an upper face of the wafer 200.

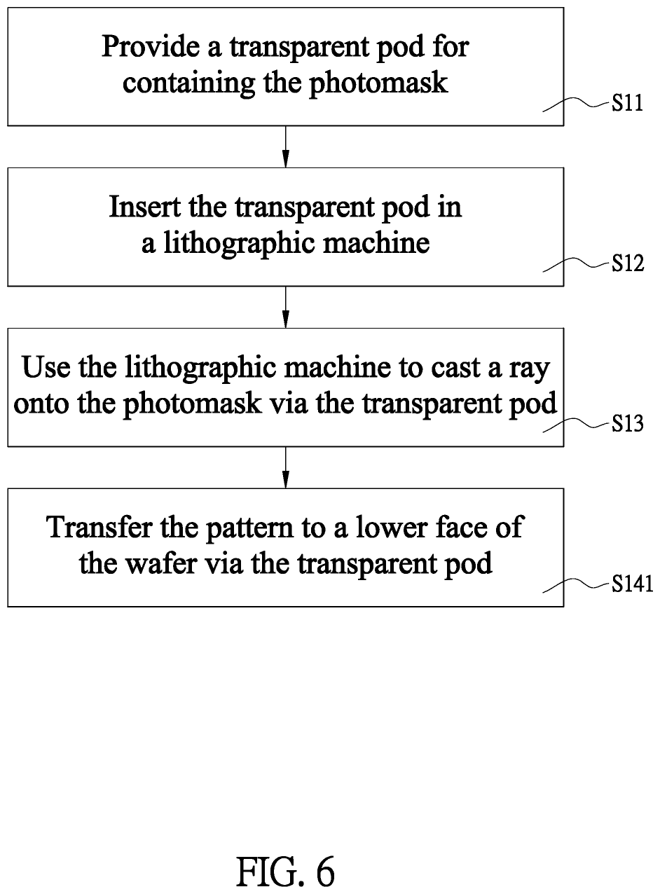

Referring to FIG. 6, there is a lithographic method by using a photomask 100 according to a second embodiment of the present invention. The photomask 100 includes a reflective layer (not shown) coated on the upper face of the photomask 100, and the pattern 105 is formed on the reflective layer.

At S11, the transparent pod is provided for containing the photomask 100.

At S12, the transparent pod is inserted in the lithographic machine 50. The transparent pod is inserted in the lithographic machine 50 after the photomask 100 is inserted in the transparent pod.

At S13, the lithographic machine 50 is used to cast the ray 51 onto the upper face of the photomask 100 through the upper lens 12.

A first portion of the ray 51 is absorbed by the pattern 105 while a second portion of the ray 51 bounces from the reflective layer. Via the upper lens 12, the second portion of the ray 51 goes to the wafer 200 that is located above the transparent pod.

At S141, the pattern 105 is transferred to a lower face of the wafer 200.

As discussed above, the photomask 100 is contained in and hence protected by the transparent pod throughout the lithographic method. Hence, the risk of contamination of the photomask 100 is minimized. Moreover, the yield of production of semiconductor produces by use of the photomask 100 is maximized. Furthermore, the size and cost of the lithographic machine 50 are minimized because there is no need to include a mechanism for taking the photomask 100 from the transparent pod to allow lithographic method of the photomask 100.

The present invention has been described via the illustration of the embodiments. Those skilled in the art can derive variations from the embodiments without departing from the scope of the present invention. Therefore, the embodiments shall not limit the scope of the present invention defined in the claims.

1. A lithographic method comprising the steps of:
providing a photomask with a pattern;
using a transparent pod to contain the photomask;
inserting the transparent pod in a lithographic machine;
using the lithograph machine to cast light onto the photomask via the transparent pod; and
transferring the pattern to a wafer.

2. The lithographic method according to claim 1, wherein the transparent pod comprises two lenses in parallel to each other, wherein the lower and upper lenses are made of transmittance equal to or larger than 90%, and wherein each of the lenses comprises a transparent portion equal to or larger than the pattern.

3. The lithographic method according to claim 2, wherein the transparent pod comprises a base and a cover for covering the base, and wherein one of the lenses is connected to the base while the remaining one of the lenses is connected to the cover.

4. The lithographic method according to claim 3, wherein the base and the cover are made of plastic except for the lenses.

5. The lithographic method according to claim 3, wherein the base and the cover are made of metal except for the lenses.

6. The transparent pod according to claim 4, wherein the lenses are made of 99.995% pure quartz.

7. A lithographic method comprising the steps of:
providing a photomask with a reflective layer and a pattern formed on the reflective layer;
using a transparent pod to contain the photomask;
inserting the transparent pod in a lithographic machine;
using the lithograph machine to cast light onto the photomask via the transparent pod, wherein a first portion of the light is absorbed by the pattern and a second portion of the light bounces from the reflective layer of the photomask; and
transferring the pattern to a wafer by using the second portion of the light.
